(19) United States
(12) Patent Application Publication
(10) Pub. No.: US 2026/0023127 A1
(43) Pub. Date: Jan. 22, 2026

(54) METHOD AND SYSTEM FOR CALIBRATION AND CORRECTION OF AN IMPEDANCE MEASUREMENT

(71) Applicant: TEXAS INSTRUMENTS INCORPORATED, Dallas, TX (US)

(72) Inventors: Bassem Ibrahim, Allen, TX (US); Dave Magee, Allen, TX (US)

(21) Appl. No.: 19/041,746

(22) Filed: Jan. 30, 2025

Related U.S. Application Data
(60) Provisional application No. 63/673,926, filed on Jul. 22, 2024.

(51) Int. Cl. G01R 31/389; G01R 31/3842; G01R 35/00

(52) U.S. Cl. CPC G01R 31/389; G01R 31/3842; G01R 35/005

(57) ABSTRACT

An apparatus comprises a calibration device; a device under test (DUT) connected in series with the calibration device; an electrical interface coupled to the calibration device; a voltage measurement circuit coupled to the electrical interface; a current measurement circuit coupled to the electrical interface; an impedance computation circuit configured to: generate a first impedance of the calibration device in the frequency domain based on first outputs of the voltage measurement circuit and of the current measurement circuit and generate a second impedance of the DUT in the frequency domain based on second outputs of the voltage measurement circuit and of the current measurement circuit; a correction circuit configured to generate parameters representing a correction function based on the first impedance and a reference frequency response of the calibration device and provide a third impedance of the DUT based on combining the parameters with the second impedance.

### RELATED APPLICATION

This application claims priority to U.S. Provisional Application No. 63/673,926, filed Jul. 22, 2024, entitled “Method and System for Calibration and Correction of Impedance Measurement,” which is hereby incorporated by reference.

### BACKGROUND

In battery electrochemical impedance spectroscopy (EIS), the sensing (or measurement) circuits include low-pass filters to reduce noise with cut-off frequency too close to the measurement frequency that may cause amplitude and phase shifts in the measured signals. These phase shifts result in a phase error in the measured impedance. In addition, the wires between each cell and the measurement circuits introduce an inductance that causes ringing with any switching activity from the excitation circuit which results in signal distortion.

In order to get the actual impedance of each cell, a correction function needs to be computed at the measurement frequency and then multiplied by the measured impedance to correct for the circuit response at a given frequency and provide the correct cell impedance. A common device calibration method to compute the correction function is performed at the factory by applying an AC signal at the inputs of the voltage and measurement circuits with constant amplitude versus frequency and sweeping the signal frequency across the full excitation frequency range. This approach is expensive and complicated. Further, it is important to consider the parasitics of the wires and the board traces used to connect the batteries in the system so that they are account for in the calibration method. Also, the calibration might need to be repeated in-vivo during the lifetime of the EIS system to account for any change in the circuit transfer function.

### SUMMARY

In one example, an apparatus comprises: a calibration device; a device under test (DUT) connected in series with the calibration device; an electrical interface coupled to the calibration device; a voltage measurement circuit coupled to the electrical interface; a current measurement circuit coupled to the electrical interface; an impedance computation circuit configured to: generate a first impedance of the calibration device in the frequency domain based on first outputs of the voltage measurement circuit and of the current measurement circuit and generate a second impedance of the DUT in the frequency domain based on second outputs of the voltage measurement circuit and of the current measurement circuit; a correction circuit configured to generate parameters representing a correction function based on the first impedance and a reference frequency response of the calibration device and provide a third impedance of the DUT based on combining the parameters with the second impedance.

In one example, an apparatus comprises an electrical interface; a memory configured to store parameters based on a frequency response of the electrical interface; a processing circuit coupled to electrical interface and configured to receive signals via the electrical interface and compute an impedance of a device under test (DUT) based on the signals and the parameters.

In one example, an apparatus comprises a first electrical interface; a second electrical interface; a memory; an impedance computation circuit having a first input, a second input, and an output, the first input and the output coupled to the memory; and a switch coupled between the first and second electrical interfaces and the second input.

In one example, an apparatus comprises a processing circuit coupled to a memory and configured to accept outputs from a voltage measurement circuit and outputs from a current measurement circuit, retrieve an impedance correction function computed on a known frequency response of a calibration component from the memory, and generate an impedance measurement of a device under test (DUT) based on the outputs from the voltage measurement circuit, the outputs from the current measurement circuit, and the impedance correction function.

In one example, an apparatus comprises a first electrical interface coupled between a calibration device and a first voltage measurement circuit, a second electrical interface coupled between a device under test (DUT) and a second voltage measurement circuit, a memory, and an impedance computation circuit having a first input, a second input, and an output, wherein the impedance computation circuit is configured to generate an impedance measurement of the DUT based on outputs of the first voltage measurement circuit and the second voltage measurement circuit in the frequency domain and outputs of a current measurement circuit in the frequency domain.

In one example, a method comprises measuring a frequency response of an electrical interface based on outputs of a voltage measurement circuit in the frequency domain and outputs of a current measurement circuit in the frequency domain, generating an impedance correction function based on the frequency response of an electrical interface, obtaining a first impedance of a device under test (DUT) via the electrical interface, and generating a second impedance of the DUT based on the impedance correction function and the first impedance of the DUT.

In one example, a method comprises measuring a first impedance of a calibration device and a second impedance of a device under test (DUT) in parallel based on outputs of a first voltage measurement circuit coupled to calibration device, a second voltage measurement circuit coupled to the DUT, and output of a current measurement circuit in the frequency domain, generating a first impedance correction function of the calibration device and a second impedance correction function of the DUT, and generating a third impedance of the DUT based on the first impedance correction function, the second impedance correction function, and the second impedance of the DUT.

### BRIEF DESCRIPTION OF THE DRAWINGS

FIG. 1 is a block diagram of an example of a frequency response measurement system.

FIG. 2 depicts an example of an equivalent circuit model representing physical effects that occur inside the battery during charging, discharging, and aging.

FIG. 3 is a block diagram of an example of an EIS system, which includes an excitation circuit to generate an excitation signal to excite the battery module (DUT) for EIS measurements.

FIG. 4 depicts an example of an EIS measurement architecture, which includes an excitation circuit connected to a battery module.

FIG. 5 is a block diagram of an example of a frequency response measurement system, which provides correction functionalities in addition to the system of FIG. 1.

FIGS. 6A and 6B depict an example of an EIS measurement architecture for one-time calibration under one-time calibration mode and measurement mode, respectively.

FIG. 7A is a flowchart illustrating an example of a method for correction function generation via the EIS measurement architecture 600 under the calibration mode. FIG. 7B is a flowchart illustrating an example of the method 700 for impedance correction via the EIS measurement architecture 600 under the measurement mode.

FIG. 8 depicts an example of an EIS measurement architecture including an integrated calibration circuit.

FIG. 9 depicts an example of an EIS measurement architecture to support simultaneous calibration and measurement.

FIG. 10 is a block diagram of an example processor platform 900 including processor circuitry structured to execute machine-readable instructions to implement the circuits and unit depicted in the examples above.

### DETAILED DESCRIPTION

The same reference numbers or other reference designators are used in the drawings to designate the same or similar (either by function and/or structure) features.

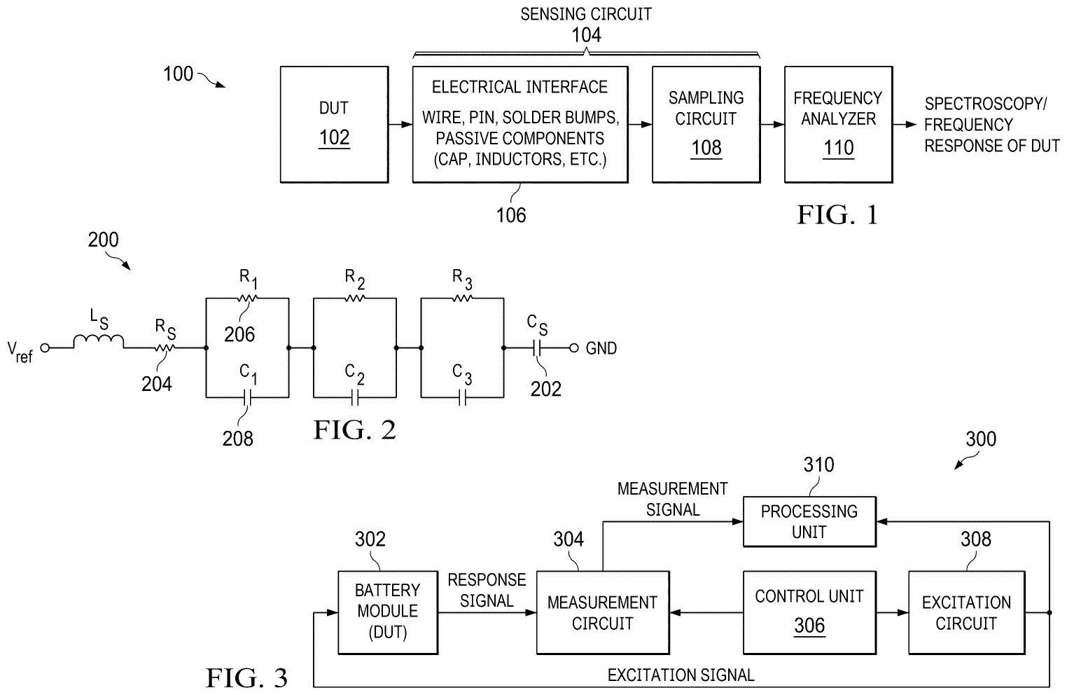

FIG. 1 is a block diagram of an example of a frequency response measurement system 100. As shown in the example of FIG. 1, the system 100 includes a device under test (DUT) 102, a sensing circuit (or measurement circuit) 104, which further includes an electrical interface 106 and a sampling circuit 108, and a frequency analyzer 110. In one example, the DUT 102 is connected to the sampling circuit 108 of the measurement circuit 104 through the electrical interface 106, wherein the electrical interface 106 comprises one or more components connecting the DUT 102 and the sampling circuit 108. For examples, one or more components include but are not limited to wires, pins, solders, bumps, and other passive components (e.g., capacitors, inductors, resistors, etc.). In one example, the sampling circuit 108 is configured to measure the voltage across and/or current through the DUT 102 by sampling at a sampling frequency, and the frequency analyzer 110 is configured to generate a frequency response of the DUT 102 through the electrical interface 106 across a full excitation frequency range according to sampled voltage and/or current of the DUT 102.

In one example, the DUT 102 in FIG. 1 can be but is not limited to a battery, which can include one or more battery cells, and the frequency response measurement system 100 is configured to measure impedance spectroscopy of the battery. Other examples of DUT 102 may include any electrochemical device that has an electrical impedance, a charge storage device (e.g., a capacitor), or other devices having a frequency response. Although a battery or a battery module is used as a non-limiting example of a DUT in the discussions below, the same or similar approaches are also appliable to measurement of other types of DUTs. Furthermore, although impedance spectroscopy is used as a non-limiting example of frequency response measurement in the discussions below, the same or similar approaches are also appliable to measurement of any frequency response of a DUT through an electrical interface.

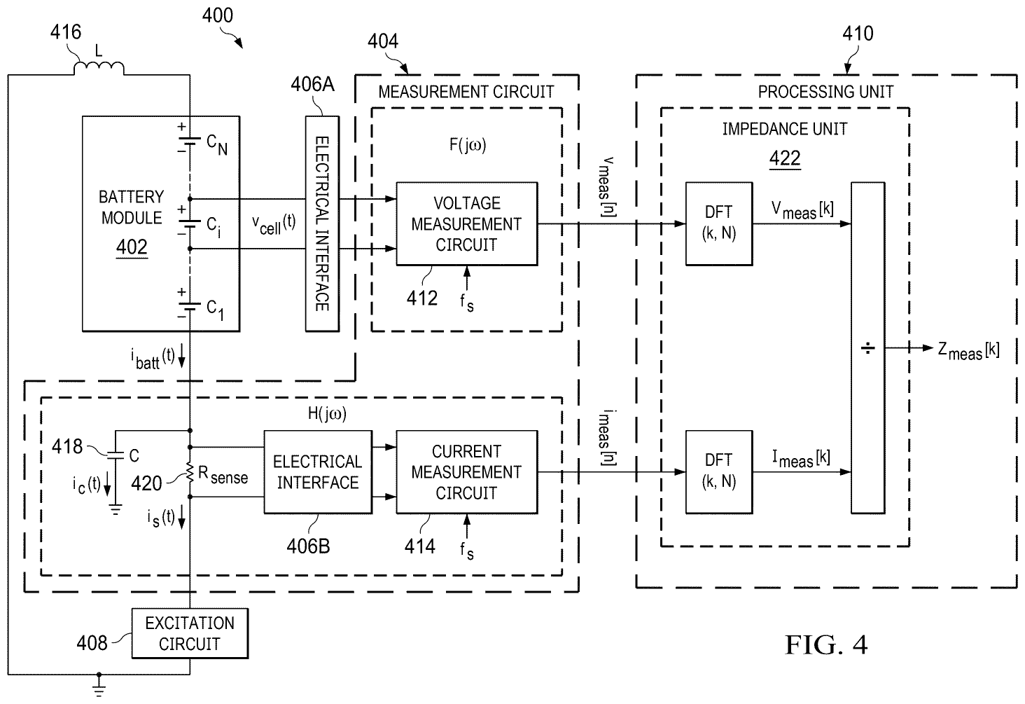

FIG. 2 depicts an example of an equivalent circuit model 200 that can represent physical effects that occur inside a battery cell during charging, discharging, and aging. As shown in FIG. 2, the circuit model 200 includes a series combination of a capacitor 202, a resistor 204, and several (e.g., 3) stages of a resistor 206 and a capacitor 208 each one, connected in parallel. The series capacitor 202 represents the charge stored in the battery cell, the resistor 204 represents the DC resistance of the battery cell, and the RC stages represent time constants for the variation of the instantaneous battery cell voltage.

The impedance of the battery cell can be determined from the equivalent circuit model 200 once the parameter values have been determined using a characterization method, which determines the appropriate parameter values under the state-of-charge (SOC), state-of-health (SOH), and environmental conditions encountered during the battery's lifetime. In one example, the characterization method involves applying an excitation signal to a battery across a range of operating conditions, and the circuit parameters that best model each battery cell of the battery can be determined from the measured responses of each battery cell to the excitation signal.

A battery cell impedance spectrum, which is the ratio between the battery cell voltage and battery cell current in the frequency domain, has a strong correlation to battery cell SOC, SOH, and internal temperature. Measurement of the battery cell impedance spectrum in order to characterize their behavior is frequently referred to as electrochemical impedance spectroscopy (EIS). EIS measurements can be used to generate battery cell models and to estimate various states of each battery cell (e.g., SOC, SOH, temperature, etc.).

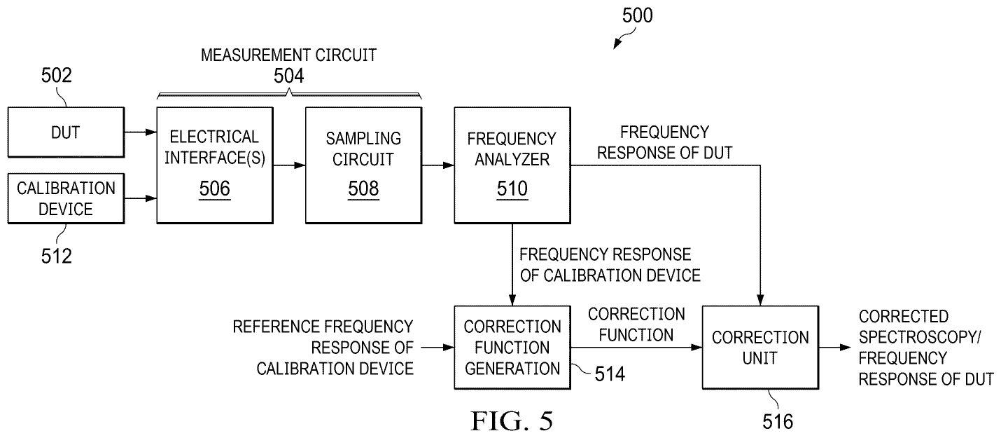

FIG. 3 is a block diagram of an example of an EIS system 300, which includes an excitation circuit 308 to generate an excitation signal to excite the battery module (DUT) 302 for EIS measurements. In one example, the excitation signal may include a single sinusoidal signal or a linear combination of several sinusoid signals referred to as a single-tone or multi-tone excitation signals, respectively. The excitation circuit 308 may receive control signals generated by a control unit 306 to control the timing, amplitude, frequency and phase of the excitation signals. A response signal (e.g., a voltage signal, a current signal, etc.) is provided by the battery module 302 in response to the excitation signal and sensed/measured by a sensing circuit (or measurement circuit) 304, which generates a measurement signal representing a result of sensing/measurement of the response signal. In one example, the excitation signal and the measurement signal can be sampled and digitally processed in a processing unit 310, which implements, e.g., the frequency analyzer 110, can be either a part of a processor or a dedicated hardware. In one example, the processing unit 310 is configured to compute a discrete Fourier transform (DFT) of the current and voltage signals in the frequency domain. The ratio of the voltage DFT value and the current DFT value is the impedance of the battery module 302.

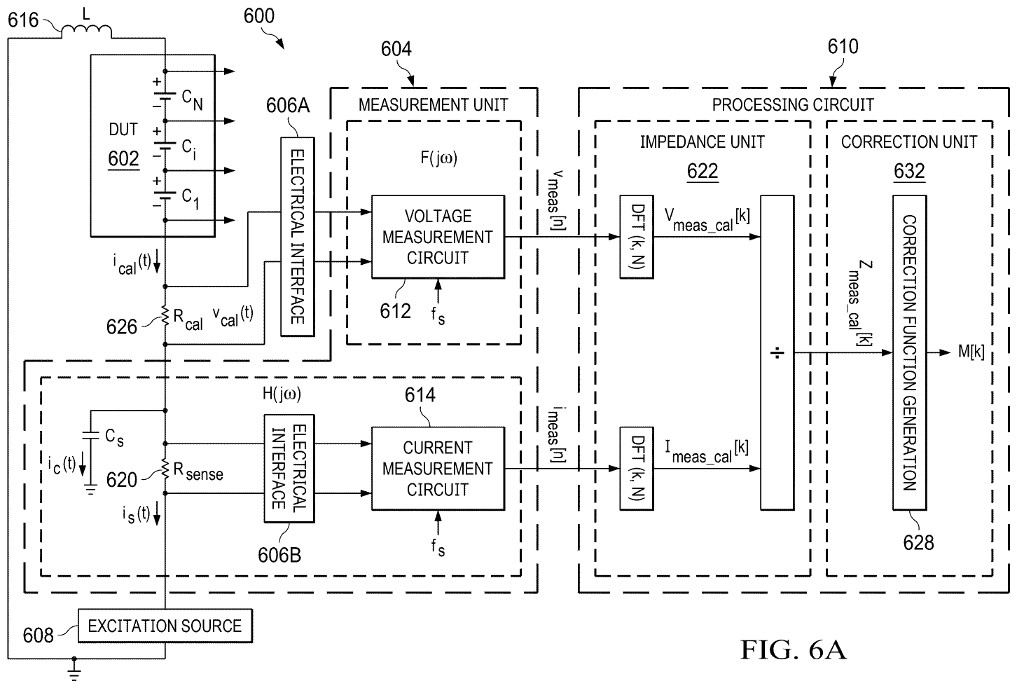

FIG. 4 depicts an example of an EIS measurement architecture 400, which includes an excitation circuit 408 connected to a battery module 402, wherein the excitation circuit 408 is responsible for applying an excitation current at excitation frequencies ωₖ to the battery module 402. As shown in FIG. 4, the sensing circuit (or measurement circuit) 404 includes a voltage measurement circuit 412 and a current measurement circuit 414 configured to measure the current signal i_{batt}(t) and the voltage response v_{batt}(t) of the battery module 402, respectively. In one example, the voltage measurement circuit 412 is coupled to the battery module 402 via an electrical interface 406A, and the current measurement circuit 414 is coupled to a sense resistor 420 via an electrical interface 406B.

The impedance of the battery module 402 in the frequency domain can be computed by dividing the voltage signal V_{batt}(jω) by the current signal I_{batt}(jω) of the battery module 402, both in the frequency domain, as follows:

$${Z}_{batt} ( j ω ) = \frac{{V}_{batt} ( j ω )}{{I}_{batt} ( j ω )}$$

In one example, the voltage measurement circuits 412 and the current measurement circuit 414 are configured to measure and sample v_{batt}(j) and i_{batt}(t) at sampling frequency fₛ to generate discrete time voltage and current signals vₘₑₐₛ[n] and iₘₑₐₛ[n], respectively. The measured voltage and current signals are then converted by the impedance unit 422 of the processing unit 410 to frequency domain signals of Vₘₑₐₛ[k] and Iₘₑₐₛ[k], respectively, at the kth excitation frequency

$${ω}_{k} = 2 π k \frac{{f}_{s}}{N}$$

using the discrete Fourier Transform (DFT), where k is the frequency bin index and N as the number of DFT points. The measured battery impedance Zₘₑₐₛ[k] at the excitation frequency ωₖ is then computed by the impedance unit 422 from frequency domain signals as follows:

$${Z}_{meas} [ k ] = \frac{{V}_{meas} [ k ]}{{I}_{meas} [ k ]}$$

Ideally, the measured impedance Zₘₑₐₛ[k] is equal to the actual impedance of the battery module 402 at the excitation frequency ωₖ of Z_{batt}(ω)|_{ω=ω}_{ₖ} if the measurement circuit 404 does not introduce error. However, the measurement circuit 404 may introduce error components to Z_{batt}(w) for various reasons. For example, the measurement circuit 404 may include low-pass filters to reduce noise. The cut-off frequency of the low-pass filters may be close to the sampling frequency of the measurement circuit 404, which may cause amplitude and phase shifts in the measured signals. These phase shifts result in a phase error in the measured impedance. In addition, the electrical interface 406A between the battery module 402 and the measurement circuit 404 introduces an inductance 416 that causes ringing with any switching activity from the excitation circuit 408, and the ringing results in signal distortion. In one example, the measurement circuit 404 may include a filtering capacitor 418 coupled between the sense resistor 420 and ground to attenuate the ringing and reduce signal distortion, but the filtering capacitor 418 may lead to the measured current iₛ(t) being different from the battery current i_{batt}(t) in amplitude and phase, causing an additional source of error in the measured impedance.

In one example, the impact of the measurement circuit 404 on the measured signals at a given frequency can be represented in the frequency domain by the transfer functions F(jω) and H(jω) for the voltage and current measurement circuits 412 and 414, respectively, where:

$$F ( j ω ) = \frac{{V}_{meas} ( j ω )}{{V}_{batt} ( j ω )} and H ( j ω ) = \frac{{I}_{meas} ( j ω )}{{I}_{batt} ( j ω )}$$

Therefore, the DFT outputs can be represented as

$${V}_{meas} [ k ] = {V}_{batt} ( j ω ) * F ( j ω ) {\vert}_{ω = {ω}_{k}}$$

$${I}_{meas} [ k ] = {l}_{batt} ( j ω ) * H ( j ω ) {\vert}_{ω = {ω}_{k}}$$

Consequently, the measured impedance can be represented as

$${Z}_{meas} [ k ] = \frac{{V}_{meas} [ k ]}{{I}_{meas} [ k ]} = \frac{{V}_{batt} ( j ω ) * F ( j ω )}{{l}_{batt} ( j ω ) * H ( j ω )} {\vert}_{ω = {ω}_{k}}$$

As a result, the measured impedance is equal to the actual impedance of the DUT 102 multiplied by a frequency dependency transfer function, G(jω) at the measurement frequency ωₖ, as follows:

$${Z}_{meas} [ k ] = {Z}_{batt} ( j ω ) * G ( j ω ) {\vert}_{ω = {ω}_{k}}$$

where G(jω) is the gain distortion function

$$( Note : G ( j ω ) = \frac{F ( j ω )}{H ( j ω )} ) .$$

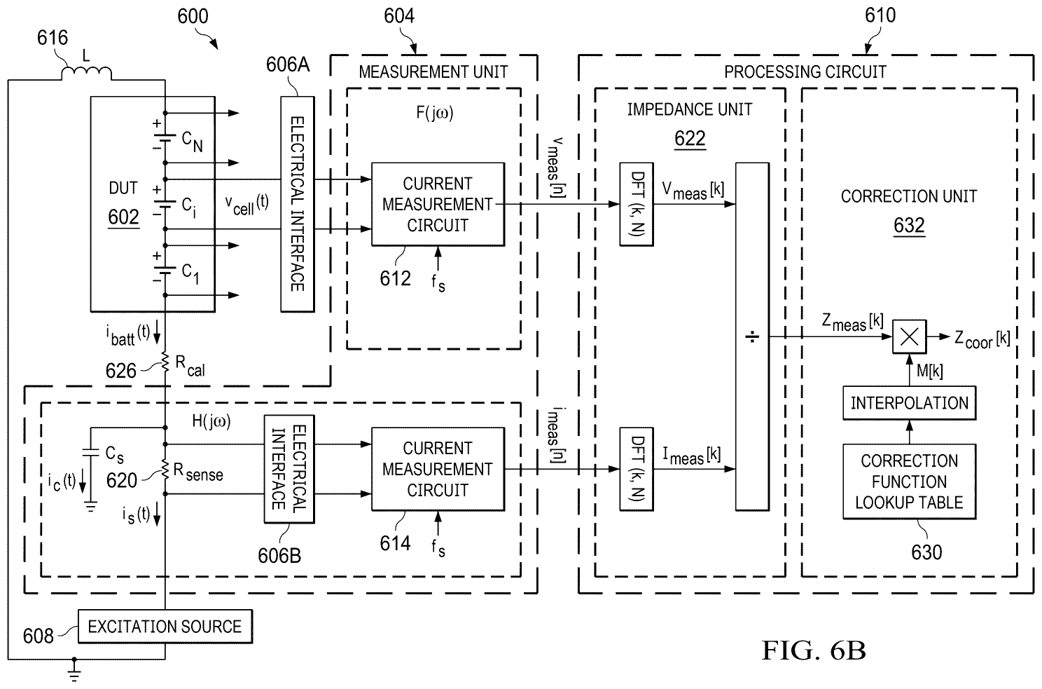

To obtain the actual battery impedance Z_{batt}(jω), a correction function M[k] (e.g., inverse of the gain distortion function) can be computed at the measurement frequency ωₖ, and then multiplied by the measured impedance Zₘₑₐₛ[k] to correct for the circuit response at a given frequency and provide the actual battery impedance Z_{batt}(jω)). FIG. 5 is a block diagram of an example of a frequency response measurement system 500, which provides correction functionalities in addition to the system 100 of FIG. 1. In addition to the corresponding components of FIG. 1, e.g., DUT 502, measurement circuit 504, electrical interface(s) 506, sampling circuit 508, and frequency analyzer 510, the system 500 further includes a calibration device 512, a correction function generation unit 514, and a correction unit 516. Note that the electrical interface(s) 506 can be either a single electrical interface or multiple matched electrical interfaces each having similar components as the electrical interface 106 discussed above.

In one example, the correction function generation unit 514 is configured to take a reference frequency response and a frequency response of the calibration device 512 generated by the frequency analyzer 510 as its input and generate the correction function as its output to the correction unit 516. The correction unit 516 then takes the correction function as its input and applies the correction function to a frequency response of the DUT 502 to generate a corrected spectroscopy/frequency response of the DUT 502.

In some examples, the calibration device 512 includes one or more passive components (e.g., resistor, capacitor, inductor, etc.) and/or one or more active components (e.g., a transistor, a switch, etc.), with a known frequency response, in order to determine the correction function of the same EIS excitation and measurement circuits. The passive component shares the same wiring between the DUT 512 and the voltage measurement circuit of the measurement circuit 504 and is along the same current path as the current measurement circuit of the measurement circuit 504. In some examples, the passive components can include a high-precision resistor with insignificant variation with temperature. Other passive components with known frequency response, such as capacitors and inductors, can also be used.

In one example, a calibration operation can be performed, in which a power source provides the passive components of the calibration device 512 with a current. The voltage across the calibration device 512 is measured and sampled using the voltage measurement circuit of the measurement circuit 504. The current is also measured by the current measurement circuit of the measurement circuit 504. With the frequency response of the calibration device 512 known, the correction function generation unit 514 is configured to compare the measured impedance Zₘₑₐₛ[k] with the known impedance of the calibration device 512 to determine the correction function M[k], which is then utilized by the correction unit 516 to generate the corrected frequency response of the DUT 502. In a case where the calibration device 512 is a high-precision resistor, which has insignificant variation with temperature, the system 500 may correct for changes in the current and voltage measurement paths due to temperature over time by running the calibration operation before each EIS measurement.

In one example, the frequency response measurement system 500 uses the calibration device 512 to measure the correction function using the same EIS excitation and measurement circuits to compare the measured impedance with the calibration device 512, which can reduce the need for any additional excitation or measurement equipment, as well as calibration cost. This approach allows the calibration to be done in the factory or integrated into the final product (e.g., electric vehicle, laptop, etc.). In some examples, the calibration can be performed one-time only, which is simple and cost-efficient. In some examples, the calibration can be performed periodically throughout the life of the device, which allows the calibration to capture changes in the measurement path (and correction function) due to, for example, aging, changes in the operation environment, etc. Furthermore, the calibration does not require interpolation for a new frequency it is performed at each EIS measurement frequency. By using a high-precision resistor as the calibration device 512, which has insignificant variation with temperature, the proposed approach can correct for changes in the current and voltage measurement paths due to temperature over time by running the calibration procedure before each EIS measurement.

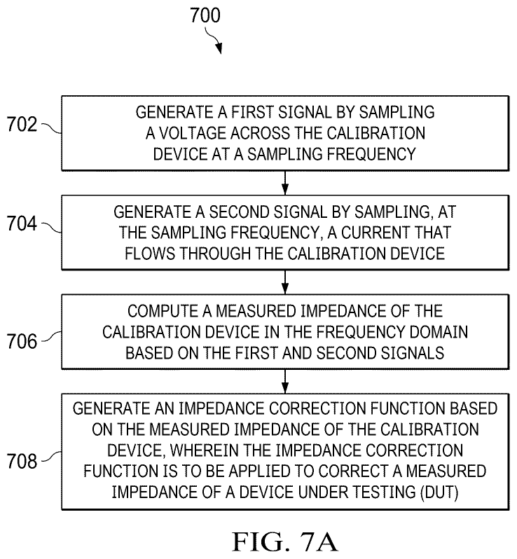

FIGS. 6A and 6B depict an example of an EIS measurement architecture 600 for one-time calibration under a calibration mode and a measurement mode, respectively. The components in the EIS measurement architecture 600 function the same as the corresponding components in the EIS measurement architecture 400 except for those discussed below. As shown in FIG. 6A, in addition to battery module 602, which can be an example of battery module 402 of FIG. 4, and measurement unit 604, which can be an example of measurement unit 404 of FIG. 4 and includes voltage measurement circuit 612 and current measurement circuit 614, the EIS measurement architecture 600 under the calibration mode further includes a calibration device 626, which is a passive component such as a high-precision, low temperature variability resistor having a resistance R_{cal}. In one example, R_{cal} is coupled to an electrical interface 606A, which is coupled to the voltage measurement circuit 612 and a processing unit 610 via wirings (introducing inductance 616). In one example, the calibration device 626 is also coupled in series with a current sense resistor Rₛₑₙₛₑ 620, which is coupled to the current measurement circuit 614 via an electrical interface 606B.

When operating under the calibration mode, the battery module 602 provides a current i_{cal}(t) through the calibration device 626 as shown in FIG. 6A. In one example, the excitation source 608 (e.g., a pulse width modulator) is also active to introduce frequency components to i_{cal}(t). The voltage across the calibration device 626, e.g., R_{cal}, defined as v_{cal}(t), is measured by the voltage measurement circuit 612 via the same electrical interface 606A through which the voltage measurement circuit 612 measures the voltage across the battery module 602 in the measurement mode as shown in FIG. 6B.

During the calibration mode, the voltage and current signals measured by the voltage measurement circuit 612 and the current measurement circuit 614, respectively, are represented as follows:

$${V}_{meas \_ cal} [ k ] = {V}_{cal} ( j ω ) * F ( j ω ) {\vert}_{ω = {ω}_{k}}$$

$${I}_{meas \_ cal} [ k ] = {I}_{cal} ( j ω ) * H ( j ω ) {\vert}_{ω = {ω}_{k}}$$

Since the calibration device 626, e.g., R_{cal} is a high-precision, low temperature variability resistor, the relation between its current and voltage can be considered constant for the impedance frequency range as follows:

$${R}_{cal} = \frac{{V}_{cal} ( j ω )}{{I}_{cal} ( j ω )}$$

Therefore, the impedance unit 622 of the processing unit 610 computes the measured impedance defined as Z_{meas_cal}[k] in calibration mode as:

$${Z}_{meas \_ cal} [ k ] = \frac{{V}_{sense \_ cal} [ k ]}{{I}_{sense \_ cal} [ k ]} = {R}_{cal} * G ( j ω ) {\vert}_{ω = {ω}_{k}}$$

The correction function generation unit 628 of the processing unit 610 then computes a gain distortion function G[k] at the measurement frequency ωₖ, which relies on the measured calibration impedance Z_{meas_cal}[k] in the calibration mode as follows:

$$G [ k ] = \frac{{Z}_{meas \_ cal} [ k ]}{{R}_{cal}}$$

And a correction function M[k] is calculated by the correction function generation unit 628 according to the following equation:

$$M [ k ] = \frac{1}{G [ k ]}$$

In one example, the correction function generation unit 628 of the correction unit 632 of the processing unit 610 is configured to compute the correction function M[k] at different excitation frequencies and store the computed correction function M[k] at different excitation frequencies in a correction function lookup table 630 of a memory of the correction unit 632 as shown in FIG. 6B. In one example, the correction function generation unit 628 is also configured to compute additional values of the correction function M[k] for a particular excitation/measurement frequency using interpolation between the nearest excitation frequency points in the correction function lookup table 630.

In the example of FIGS. 6A and 6B, processing circuit 610 can include a processor (e.g., a digital signal processor) configured to execute software instructions to implement impedance unit 622 and correction unit 632 (including correction function generation unit 628), where these units can be software modules. In some examples, processing circuit 610 can include an application specific integrated circuit (ASIC), a programmable logic device (e.g., field effect programmable logic gate), etc., and includes logic circuitries to implement these units. Also, voltage measurement circuit 612, current measurement circuit 614, and processing circuit 610 can be part of a packaged integrated circuit (IC), or can be in different packaged ICs.

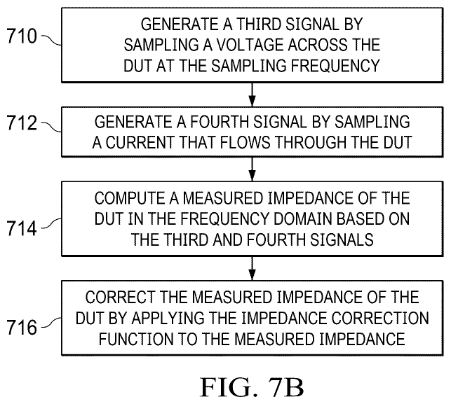

FIG. 7A is a flowchart illustrating an example of a method 700 for correction function generation via the EIS measurement architecture 600 under the calibration mode, which switches the input of the voltage measurement circuit 612 to the calibration device 626 to measure v_{cal}(t). An impedance measurement is then performed by the impedance unit 622 at the corresponding frequency index k to get the measured calibration impedance reading of Z_{meas_cal}[k], which is used by the correction function generation unit 628 to calculate the correction function M[k].

At block 702, a first signal (e.g., a first voltage measurement signal) is generated by measurement unit 604 by sensing/sampling a voltage across the calibration device is at a sampling frequency.

At block 704, a second signal (e.g., a first current measurement signal) is generated by measurement unit 604 by sensing/sampling a current that flows through the calibration device at the sampling frequency.

At block 706, a measured impedance of the calibration device in the frequency domain is computed by impedance unit 622 of processing circuit 610, at a set of calibration frequencies, based on the first and second signals. In some examples, the set of calibration frequencies can be the same as a set of EIS measurement frequencies. In some examples, the calibration frequencies can be different from the EIS measurement frequencies.

At block 708, an impedance correction function is generated by correction function generation unit 628 of processing circuit 610, at the set of calibration frequencies, based on the measured calibration impedance of the calibration device, wherein the impedance correction function is to be applied to a measured impedance of a device under testing (DUT), to be obtained in the measurement mode, to correct the measured impedance.

When operating under the measurement mode, the calibration device 626 is swapped out with the DUT/battery module 602, which impedance is to be measured, swapped in and connected to the electrical interface 606A instead. The measurement circuit 604 can measure (e.g., sense/sample, and digitize) the voltage and current of the battery module 602 at different measurement frequencies, respectively, as discussed above. The impedance module 622 of the processing unit 610 can computes a measured impedance of the battery module 602 in the frequency domain, Zₘₑₐₛ[k], at the different measurement frequencies represented by different frequency bin indices k. The correction unit 632 of the processing unit 610 then looks up the correction function M[k] at the measurement frequency computed and stored in the correction function lookup table 630 of the correction unit 632 during the impedance measurement mode, and utilize the correction function M[k] to calculate the corrected impedance Z_{corr}[k] that matches the actual impedance of the battery module 602 by multiplying the measured impedance Zₘₑₐₛ[k] by the M[k] as follows:

$${Z}_{corr} [ k ] = {Z}_{meas} [ k ] * M [ k ] = {Z}_{batt} ( j ω ) {\vert}_{ω = {ω}_{k}}$$

FIG. 7B is a flowchart illustrating an example of the method 700 for impedance correction via the EIS measurement architecture 600 under the measurement mode, which starts by switching the input of the voltage measurement circuit 612 to terminals of the DUT 602 through the electrical interface 606A to measure v_{batt}(t) followed by measuring the impedance of the DUT 602 Zₛₑₙₛₑ[k] via the impedance module 622 of the processing unit 610. The correction unit 632 of the processing unit 610 can compute the corrected impedance Z_{corr}[k] of the DUT 602 by multiplying Zₛₑₙₛₑ[k] with the correction function M[k].

At block 710, a third signal (e.g., a second voltage measurement signal) is generated by measurement unit 604 by sensing/sampling a voltage across the DUT at the sampling frequency.

At block 712, a fourth signal (e.g., a second current measurement signal) is generated by measurement unit 604 by sensing/sampling, at the sampling frequency, the current that flows through the sense resistor.

At block 714, a measured impedance of the DUT in the frequency domain is computed by impedance unit 622 at the set of measurement frequencies based on the third and fourth signals.

At block 716, the measured impedance is corrected by correction unit 632 by applying the impedance correction function to measured impedance at the set of measurement frequencies.

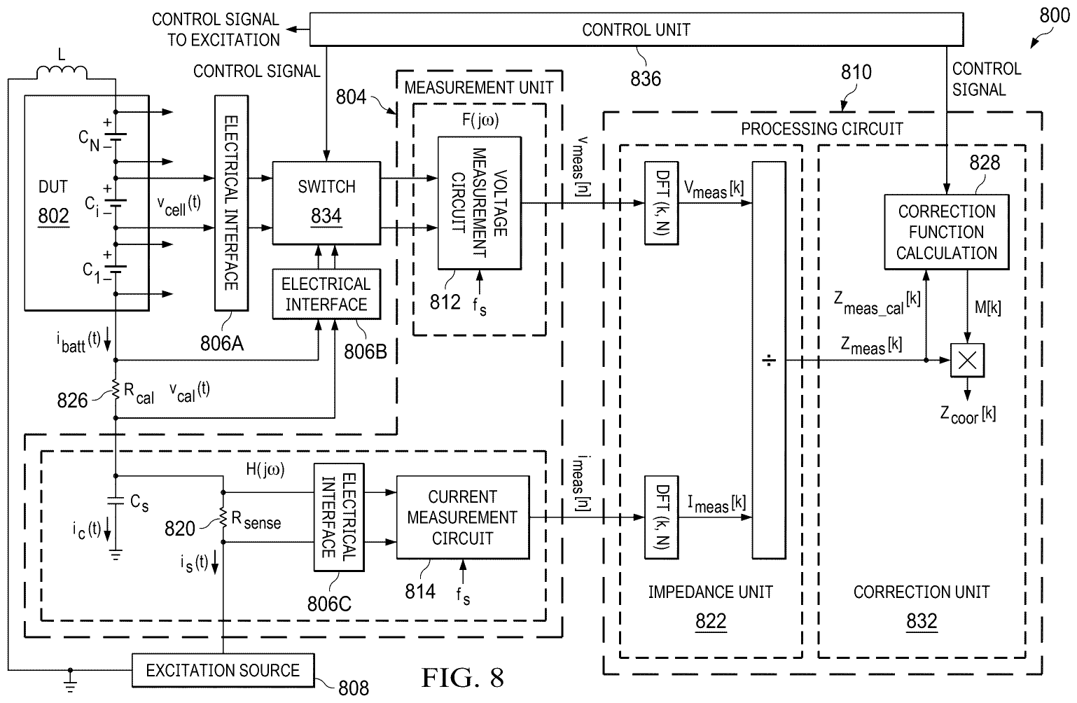

FIG. 8 depicts an example of an EIS measurement architecture 800 including an integrated calibration circuit. The components in the EIS measurement architecture 800 function the same as the corresponding components in the EIS measurement architecture 600 except for those discussed below. As shown in FIG. 8, in addition to measurement unit 804, which can be an example of measurement unit 604 of FIG. 6 and includes voltage measurement circuit 812 and current measurement circuit 814, and processing circuit 810, which can be an example of processing circuit 610 of FIG. 6 and includes impedance unit 822 and correction unit 832 (including correction function generation unit 828), the EIS measurement architecture 800 includes two electrical interfaces, first electrical interface 806A and second electrical interface 806B, that are coupled to the battery module 802 and the calibration device 826, respectively, a switch 834 that switches between the two electrical interfaces 806A and 806B, and a control unit 836 that controls the switch 834. In some examples, a third electrical interface 806C couples the sense resistor 820 to the current measurement circuit 814. As shown in FIG. 8, the calibration device 826 includes a passive component (such as a high-precision, low temperature variability resistor with resistance R_{cal}) coupled in series with the battery module 802. The switch 834 is positioned close to and coupled to the battery module 802 and the calibration device 826 via the first electrical interface 806A and the second electrical interface 806B, respectively. The switch 834 is further coupled to the voltage measurement circuit 812 through wiring. Voltage measurement circuit 812, current measurement circuit 814, switch 834, and processing circuit 810 can be part of a packaged integrated circuit (IC), or can be in different packaged ICs.

When the EIS measurement architecture 800 operates in the calibration mode, the switch 834 connects the first electrical interface 806A (and the calibration device 826) to the voltage measurement circuit 812. When the EIS measurement architecture 800 operates in the measurement mode, the switch 834 connects the second electrical interface 806B (and the battery module 802) to the voltage measurement circuit 812. In one example, the switch 834 switches between the calibration device 826 in the calibration mode and the battery module 802 in the measurement mode continuously, wherein the switch 834 is controlled by a control signal from the control unit 836. In one example, the control unit 836 is also configured to control the correction unit 632 to switch between correction function generation under the calibration mode and the measured impedance correction under the measurement mode. In one example, the control unit 836 is further configured to control the excitation source 808 via an excitation control signal.

In one example, both the calibration mode and the measurement mode of the EIS measurement architecture 800 can operate at the same excitation frequencies, which can reduce the need for extrapolation and computation complexity for the correction function computation. Also, as described above, the calibration mode can be activated before each EIS measurement in the measurement mode and at different temperatures, which can correct for changes in the current and/or voltage measurement paths due to temperature over time.

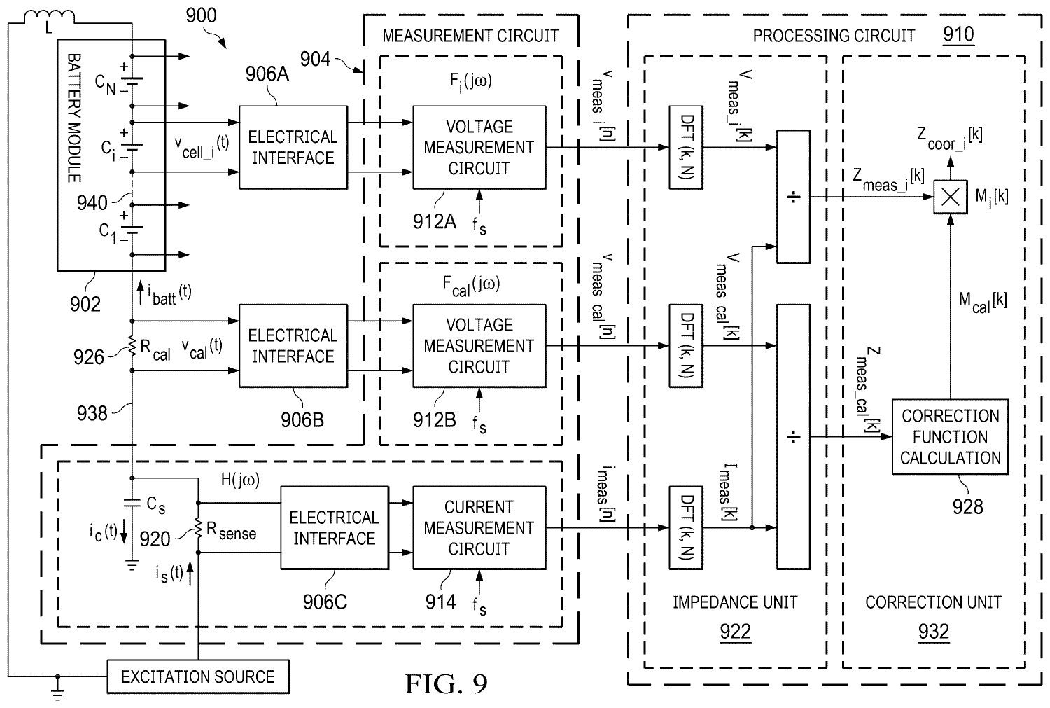

FIG. 9 depicts an example of an EIS measurement architecture 900 to support simultaneous calibration and measurement. The components in the EIS measurement architecture 900 function the same as the corresponding components in the EIS measurement architecture 800 except for those discussed below. As shown in FIG. 9, in addition to measurement unit 904, which can be an example of measurement unit 804 of FIG. 8 and includes voltage measurement circuit 912 and current measurement circuit 914, and processing circuit 910, which can be an example of processing circuit 810 of FIG. 8 and includes impedance unit 922 and correction unit 932 (including correction function generation unit 928), the EIS measurement architecture 900 further includes a dedicated voltage calibration channel 938 comprising an additional voltage measurement circuit 912B and an electrical interface 906B coupled to the calibration device 926. The voltage calibration channel 938 is in parallel to one or more voltage measurement channels 940s each comprising a voltage measurement circuit 912A and an electrical interface 906A coupled to the battery module 902 (or one of the battery cells of the battery module 902). In some examples, an electrical interface 906C couples the sense resistor 920 to the current measurement circuit 914. The voltage calibration channel 938 is configured to measure the voltage of the calibration device 926 in parallel to the voltage measurement channels 940s, which measure the voltages of the battery module 902 and/or its battery cells at the same time to calculate the impedance correction functions for the voltage measurement channels 940s. As such, the EIS measurement architecture 900 enables simultaneous calibration and measurement by using the dedicated voltage calibration channel 938 in parallel to the voltage measurement channels 940s, while skipping the switch 834 (and the optional control unit 836) of the EIS measurement architecture 800, which controls which of the battery module and the calibration device connects to the single voltage measurement circuit via one of the two electrical interfaces, respectively, as discussed above.

In one example where the battery module 902 includes a plurality of battery cells, C₁, . . . , C_{N} as shown in FIG. 9, the EIS measurement architecture 900 operates as a multi-cell monitoring system that uses parallel voltage measurement channels 940s to measure the voltage and impedance of each of the battery cells simultaneously. Specifically, the measured impedance Z_{meas_i}[k] for the i^{th} battery cell of the battery module 902 can be calculated as:

$${Z}_{meas \_ i} [ k ] = {Z}_{cell \_ i} ( j ω ) * \frac{{F}_{i} ( ω )}{H ( j ω )} {\vert}_{ω = {ω}_{k}}$$

Where Fᵢ(jω) is the transfer function of the voltage measurement channel i, and H(jω) is the transfer function of the current measurement circuit 914. The correction function Mᵢ[k] for the voltage measurement channel connecting to the i^{th} battery cell can be calculated as:

$${M}_{i} [ k ] = \frac{{F}_{cal} ( j ω )}{{F}_{i} ( j ω )} {\vert}_{ω = {ω}_{k}}$$

where F_{cal}(jω) is the transfer function of the voltage calibration channel 938.

In one example, the correction function Hᵢ[k] is pre-computed and stored in a memory for each voltage measurement channel 940 by applying the same input to the voltage measurement channels 940s and the voltage calibration channel 938 and then calculating the ratio between their outputs at each frequency ωₖ. In one example, the correction function for the voltage calibration channel 938 M_{cal}[k] can be calculated as:

$${M}_{cal} [ k ] = \frac{{R}_{cal}}{{Z}_{meas \_ cal} [ k ]} = \frac{H ( j ω )}{{F}_{cal} ( j ω )} {\vert}_{ω = {ω}_{k}}$$

The corrected impedance for the i^{th} battery cell can then be calculated as:

$${Z}_{corr \_ i} [ k ] = {Z}_{meas \_ i} [ k ] * {M}_{i} [ k ] * {M}_{cal} [ k ] = {Z}_{cell \_ i} ( j ω ) {\vert}_{ω = {ω}_{k}}$$

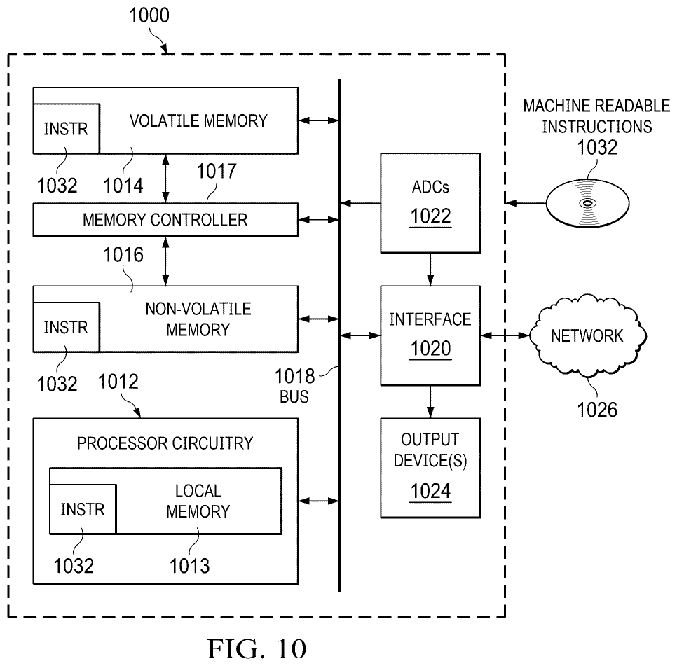

FIG. 10 is a block diagram of an example processor platform 1000 including processor circuitry structured to execute machine-readable instructions to implement the circuits and unit depicted in the examples above. Processor platform 1000 of the illustrated example can include processor circuitry 1012. The processor circuitry 1012 of the illustrated example includes hardware. For example, processor circuitry 1012 can be implemented by one or more integrated circuits, logic circuits, FPGAs, microprocessors, Central Processing Units (CPUs), Graphical Processing Units (GPUs), Digital Signal Processors (DSPs), and/or microcontrollers from any desired family or manufacturer. Processor circuitry 1012 can be implemented by one or more semiconductor-based (e.g., silicon-based) devices. For example, processor circuitry 1012 can implement the processing unit(s) and control unit(s) discussed above.

Processor circuitry 1012 of the illustrated example can include a local memory 1013 (e.g., a cache, registers, etc.). Processor circuitry 1012 of the illustrated example is in communication with a computer-readable storage device such as a main memory including a volatile memory 1014 and a non-volatile memory 1016 by a bus 1018. The volatile memory 1014 can be implemented by, for example, Synchronous Dynamic Random Access Memory (SDRAM), Dynamic Random Access Memory (DRAM), RAMBUS® Dynamic Random Access Memory (RDRAM®), and/or any other type of RAM device. The non-volatile memory 1016 may be implemented by programmable read-only memory, flash memory and/or any other desired type of non-volatile memory device. Access to the main memory 1014, 1016 of the illustrated examples can be controlled by a memory controller 1017.

The processor platform 1000 of the illustrated example also includes interface circuitry 1020 to output device(s) 1024 and with network 1026. The interface circuitry 1020 may be implemented by hardware in accordance with any type of interface standard, such as an Inter-Integrated Circuit (I2C) interface, a Serial Peripheral Interface (SPI), an Ethernet interface, a universal serial bus (USB) interface, a Bluetooth® interface, a near field communication (NFC) interface, a Peripheral Component Interconnect (PCI) interface, and/or a Peripheral Component Interconnect Express (PCIe) interface.

In the illustrated example, one or more input ADCs 1022 are connected to bus 1018. The ADCs 1022 can convert analog signals to digital signals for processing by the processor circuitry 1012.

Machine-readable instructions 1032 can be stored in volatile memory 1014 and/or non-volatile memory 1016. Upon execution by the processor circuitry 1012, the machine-readable instructions 1032 cause the processor platform 1000 to perform any or all of the functionality described herein attributed to the systems and architectures discussed above.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

Also, in this description, the recitation “based on” means “based at least in part on.” Therefore, if X is based on Y, then X may be a function of Y and any number of other factors.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

In this description, unless otherwise stated, “about,” “approximately” or “substantially” preceding a parameter means being within +/−10 percent of that parameter or, if the parameter is zero, a reasonable range of values around zero.

Modifications are possible in the described embodiments, and other embodiments are possible, within the scope of the claims.

What is claimed is:

1. An apparatus comprising:
a calibration device;
a device under test (DUT) connected in series with the calibration device;
an electrical interface coupled to the calibration device;
a voltage measurement circuit coupled to the electrical interface;
a current measurement circuit coupled to the electrical interface;
an impedance computation circuit configured to:
generate a first impedance of the calibration device in frequency domain based on first outputs of the voltage measurement circuit and of the current measurement circuit; and
generate a second impedance of the DUT in the frequency domain based on second outputs of the voltage measurement circuit and of the current measurement circuit;
a correction circuit configured to
generate parameters representing a correction function based on the first impedance and a reference frequency response of the calibration device; and
provide a third impedance of the DUT based on combining the parameters with the second impedance.

2. The apparatus of claim 1, wherein the calibration device includes a passive component.

3. The apparatus of claim 1, wherein the calibration device includes an active device.

4. The apparatus of claim 1, further comprising a second electrical interface coupled to the DUT, wherein the electrical interface is a first electric interface.

5. The apparatus of claim 4, further comprising a switch coupled between the first and the second electrical interfaces and also coupled to the voltage measurement circuit.

6. The apparatus of claim 4, wherein each of the first and second electrical interfaces includes one or more pins, connectors, wires, board traces, bumps, and passive devices.

7. The apparatus of claim 1, wherein the impedance computation circuit and the correction circuit are within a single chip.

8. An apparatus comprising:
an electrical interface;
a memory configured to store parameters based on a frequency response of the electrical interface; and
a processing circuit coupled to electrical interface and configured to:
receive signals via the electrical interface; and
compute an impedance of a device under test (DUT) based on the signals and the parameters.

9. The apparatus of claim 8, further comprising a calibration device that includes a passive component.

10. The apparatus of claim 9, wherein the calibration device includes an active device.

11. The apparatus of claim 8, further comprising a second electrical interface coupled to the DUT, wherein the electrical interface is a first electric interface.

12. The apparatus of claim 11, further comprising a switch coupled between the first and the second electrical interfaces and also coupled to a voltage measurement circuit.

13. The apparatus of claim 11, wherein each of the first and second electrical interfaces includes one or more pins, connectors, wires, board traces, bumps, and passive devices.

14. An apparatus comprising:
a first electrical interface;
a second electrical interface;
a memory;
an impedance computation circuit having a first input, a second input, and an output, the first input and the output coupled to the memory; and
a switch coupled between the first and second electrical interfaces and the second input.

15. The apparatus of claim 14, wherein the impedance computation circuit is configured to generate an impedance measurement of a calibration device or a device under test (DUT) based on outputs of a voltage measurement circuit in frequency domain and outputs of a current measurement circuit in frequency domain.

16. The apparatus of claim 15, wherein the first electrical interface is coupled between the switch and the calibration device.

17. The apparatus of claim 15, wherein the second electrical interface is coupled between the switch and the DUT.

18. An apparatus comprising:
a memory; and
a processing circuit coupled to the memory and configured to:
receive outputs from a voltage measurement circuit and outputs from a current measurement circuit;
receive an impedance correction function computed on a known frequency response of a calibration component from the memory; and
generate a signal representing an impedance of a device under test (DUT) based on the outputs from the voltage measurement circuit, the outputs from the current measurement circuit, and the impedance correction function.

19. The apparatus of claim 18, wherein the device under test includes an electrochemical device that has an electrical impedance.

20. The apparatus of claim 19, wherein the electrochemical device is a battery module that includes one or more battery cells.

21. The apparatus of claim 18, further comprising:
a control unit is configured to control the correction circuit to switch between a calibration mode and a measurement mode.

22. An apparatus comprising:
a first electrical interface coupled between a calibration device and a first voltage measurement circuit;
a second electrical interface coupled between a device under test (DUT) and a second voltage measurement circuit;
a memory; and
an impedance computation circuit having a first input, a second input, and an output,
wherein the impedance computation circuit is configured to generate a signal representing an impedance of the DUT based on outputs of the first voltage measurement circuit and the second voltage measurement circuit in frequency domain and outputs of a current measurement circuit in frequency domain.

23. A method, comprising:
determining a frequency response of an electrical interface based on outputs of a voltage measurement circuit in frequency domain and outputs of a current measurement circuit in frequency domain;
generating an impedance correction function based on the frequency response of an electrical interface;
determining a first impedance of a device under test (DUT) based on signals received via the electrical interface; and
generating a second impedance of the DUT based on the impedance correction function and the first impedance of the DUT.

24. The method of claim 23, further comprising:
generating the impedance correction function by comparing the frequency response of an electrical interface to a known frequency response of a calibration device.

25. The method of claim 23, further comprising:
connecting the electrical interface to a calibration device in a calibration mode;
generating the impedance correction function based on an impedance measurement of the calibration device;
connecting the electrical interface to the DUT in a measurement mode to generate the first impedance of the DUT.

26. The method of claim 25, wherein the electrical interface is a first electrical interface, and the method further comprises:
connecting the voltage measurement circuit to a calibration component via the first electrical interface;
generating an impedance correction function based on an impedance measurement of a calibration device;
connecting the voltage measurement circuit to a device under test (DUT) via a second electrical interface;
generating an impedance measurement of the device under test;
correcting the impedance measurement of the device under test by applying the impedance correction function to the impedance measurement.

27. The method of claim 26, further comprising:
switching connection to the voltage measurement circuit between the first electrical interface and the second electrical interface responsive to switching between the calibration mode and the measurement mode.

28. A method, comprising:
determining a first impedance of a calibration device and a second impedance of a device under test (DUT) based on outputs of a first voltage measurement circuit coupled to calibration device, a second voltage measurement circuit coupled to the DUT, and output of a current measurement circuit in frequency domain;
determining a first impedance correction function of the calibration device and a second impedance correction function of the DUT based on the first impedance of the calibration device; and
generating a signal representing a third impedance of the DUT based on the first impedance correction function, the second impedance correction function, and the second impedance of the DUT.
